(19) United States
(12) Patent Application Publication
(10) Pub. No.: US 2010/0237413 A1
(43) Pub. Date: Sep. 23, 2010

(54) Semiconductor device and method for manufacturing semiconductor device

(75) Inventor: Hiroki Kasai, Miyagi (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/659,161

(22) Filed: Feb. 26, 2010

(30) Foreign Application Priority Data
Mar. 23, 2009 (JP) 2009-069687

(51) Int. Cl. H01L 21/336; H01L 29/78

(52) U.S. Cl. 257/336; 438/286; 257/E29.261; 257/E21.417

(57) ABSTRACT

A semiconductor device has a LOCOS film formed on at least one of a drain side and a source side of a semiconductor substrate surface. A gate oxide film connected to the LOCOS film is formed on the semiconductor substrate surface. A conductive film is formed to cover the gate oxide film and the LOCOS film. A gate electrode is formed by etching the conductive film such that an end portion of the conductive film is positioned above the LOCOS film. The LOCOS film is etched such that an end portion of the LOCOS film is in alignment with an end portion of the gate electrode, thereby forming a recessed portion in a part of the semiconductor substrate surface from which the LOCOS film has been removed. A side wall spacer is formed to cover a side surface of the gate electrode such that a bottom surface of the side wall spacer contacts a surface of the recessed portion. A drain region and a source region are formed by doping a impurity to the semiconductor substrate surface on either side of the gate electrode and the side wall spacer.

### BACKGROUND OF THE INVENTION

1. Field of the Invention

The present invention relates to a semiconductor device, and more particularly to a laterally diffused metal-oxide-semiconductor (an LD-MOS).

2. Description of the Related Art

An LD-MOS is widely used in the field of semiconductors requiring a high withstand voltage and a high output , such as ICs for switching power supplies or for automotive applications. FIG. 1 shows an example of the structure of a conventional LD-MOS. A p-body region 5 composed of a p-type semiconductor is formed in a surface area of an n-type semiconductor layer 1. A source region 7 composed of an n-type semiconductor and a contact region 9 which is adjacent to the source region 7 and is composed of a highly-doped p-type semiconductor are formed in a surface area of the p-body region 5. A comparatively lightly-doped n-type semiconductor layer 6 is formed in the surface area of the n-type semiconductor layer 1 in a position separated from the p-body region 5. A drain region 8 composed of a comparatively highly-doped n-type semiconductor is formed in a surface area of the n-type semiconductor layer 6. A gate oxide film 3 is formed in such a way as to contact to the surface of the source region 7, the p-body region 5, and the n-type semiconductor layer 1. A LOCOS film 2 having a greater thickness than a film thickness of the gate oxide film 3 is connected to an end portion of the gate oxide film 3 on the drain side. The LOCOS film 2 is adjacent to the n-type semiconductor layer 6 and the drain region 8. A gate electrode 4 is formed to cover the gate oxide film 3 and a part of the LOCOS film 2. In a LD-MOS having such a structure, the gate oxide film is formed as thin as possible to improve driving ability. By disposing the LOCOS film 2 having a comparatively large film thickness below the end portion on the drain side of the gate electrode 4, a gate-drain electric field during an operation is relaxed, and therefore the gate-drain withstand voltage can be increased.

Japanese Patent Application Laid-open No. 07-066400 discloses semiconductor device comprising gate oxide film whose film thickness in a center portion is thinner than a film thickness in end portions.

### SUMMARY OF THE INVENTION

In the conventional LD-MOS structure shown in FIG. 1, the gate-drain withstand voltage is dependent on a distance d1 between the end portion on the drain side of the gate electrode 4 and the end portion on the drain side of the LOCOS film 2. Therefore, the distance d1 must be sufficient to obtain a desired gate-drain withstand voltage. However, the distance d1 has a manufacturing tolerance for alignment errors of masks used in a process for forming the LOCOS film 2, a process for patterning the gate electrode 4 and so on. Therefore, in order to ensure a desired withstand voltage even if the distance d1 varies to a lower limit side of the tolerance, a formation region of the LOCOS film 2 must be enlarged in consideration of the variation in the distance d1. It leads to an increase in element size.

The present invention has been contrived in view of the above-described problems, and an object is to provide a semiconductor device and a method for manufacturing a semiconductor device with which a gate-drain (or gate-source) withstand voltage can be secured without an accompanying increase in element size.

A method for manufacturing a semiconductor device according to the present invention is a method for manufacturing a semiconductor device having a MOS structure, including the steps of: forming a LOCOS film on at least one of a drain side and a source side of a semiconductor substrate surface; forming a gate oxide film connected to the LOCOS film on the semiconductor substrate surface; forming a conductive film to cover the gate oxide film and the LOCOS film; forming a gate electrode by etching the conductive film such that an end portion of the conductive film is positioned above the LOCOS film; etching the LOCOS film such that an end portion of the LOCOS film is in alignment with an end portion of the gate electrode, thereby forming a recessed portion in a part of the semiconductor substrate surface from which the LOCOS film has been removed; forming a side wall spacer to cover a side surface of the gate electrode such that a bottom surface of the side wall spacer contacts a surface of the recessed portion; and forming a drain region and a source region by doping a impurity to the semiconductor substrate surface on either side of the gate electrode and the side wall spacer.

Further, a semiconductor device according to the present invention is a semiconductor device having a MOS structure, including: a gate oxide film including a thick portion that is formed on at least one of a drain side and a source side of a semiconductor substrate surface and has a greater film thickness than another part of the gate oxide film; a gate electrode provided on the gate oxide film; a side wall spacer that covers a side surface of the gate electrode on the side formed with the thick portion; and a drain region and a source region provided on either side of the gate electrode and the side wall spacer on the semiconductor substrate surface, wherein the semiconductor substrate includes a recessed portion having a lower surface than another part, and a bottom surface of the side wall spacer contacts a surface of the recessed portion.

With the semiconductor device and method for manufacturing a semiconductor device according to the present invention, a gate-drain (or gate-source) withstand voltage can be secured without an accompanying increase in element size.

### BRIEF DESCRIPTION OF THE DRAWINGS

FIG. 1 is a cross-sectional view showing the structure of a conventional LD-MOS;

FIG. 2 is a cross-sectional view showing the structure of an LD-MOS according to an embodiment of the present invention; and

FIGS. 3A to 3J are cross-sectional views showing steps of a process for manufacturing the LD-MOS according to the embodiment of the present invention.

### DETAILED DESCRIPTION OF THE INVENTION

An embodiment of the present invention will be described below with reference to the drawings. The same reference numerals are used to denote substantially the same or like constituents or parts throughout the figures cited below.

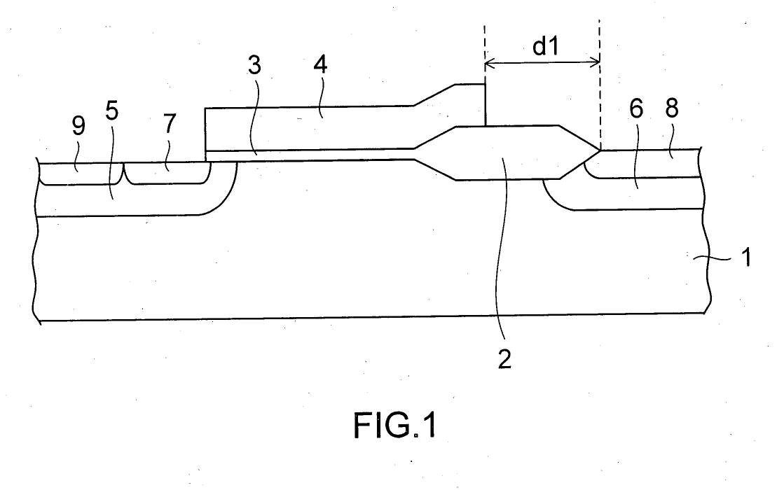

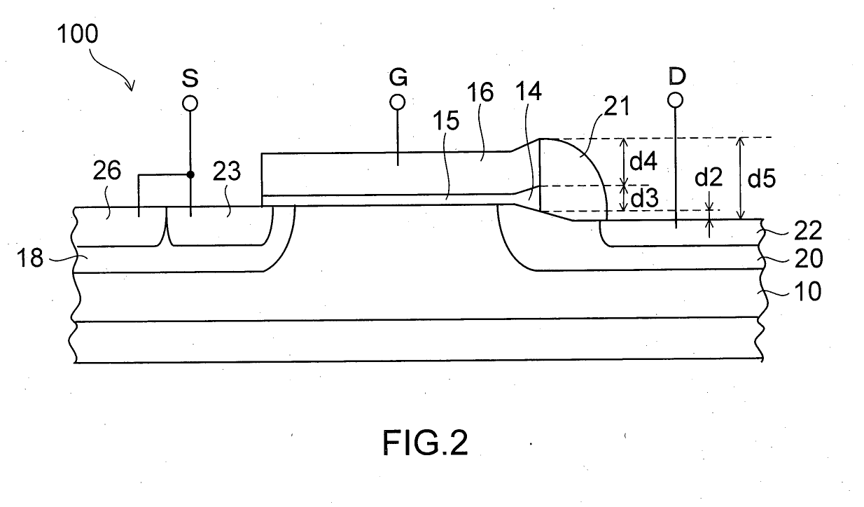

FIG. 2 is a cross-sectional view showing the structure of an LD-MOS 100 according to the embodiment of the present invention. A p-body region 18 composed of a p-type semiconductor is formed in a surface area of an n-type semiconductor layer 10. A source region 23 composed of an n-type semiconductor and body contact region 26 which is adjacent to the source region 23 and is composed of a highly-doped p-type semiconductor are formed in a surface area of the p-body region 18. An electric field relaxation layer 20 composed of a comparatively lightly-doped n-type semiconductor is formed in the surface area of the n-type semiconductor layer 10 in a position separated from the p-body region 18. A drain region 22 composed of a comparatively highly-doped n-type semiconductor is formed in a surface area of the electric field relaxation layer 20. A gate oxide film 15 is formed in such a way as to contact to the surface of the source region 23, the p-body region 18, and the n-type semiconductor layer 10. The gate oxide film 15 has a thick portion 14 at the end portion on the drain side. The thick portion 14 is formed by patterning a LOCOS film, and has a greater film thickness than other part of the gate oxidation layer 15. A gate electrode 16 is formed on the gate oxide film 15 including the thick portion 14. A side wall spacer 21 composed of an insulator is formed adjacent to the end portion on the drain side of the gate electrode 16. The side wall spacer 21 is provided to cover the surface of the electric field relaxation layer 20. The side wall spacer 21 is interposed between the gate electrode 16 and the drain region 22, and has a substantially identical function to the LOCOS film 2 shown in FIG. 1. As will be described below, the drain region 22 is formed by implementing ion implantation using the side wall spacer 21 as a mask, and therefore the electric field relaxation layer 20 extends between the gate electrode 16 and the drain region 22. The electric field relaxation layer 20 has a lower impurity concentration than the drain region 22. Therefore the electric field relaxation layer 20 has a function to relax a gate-drain electric field during an operation.

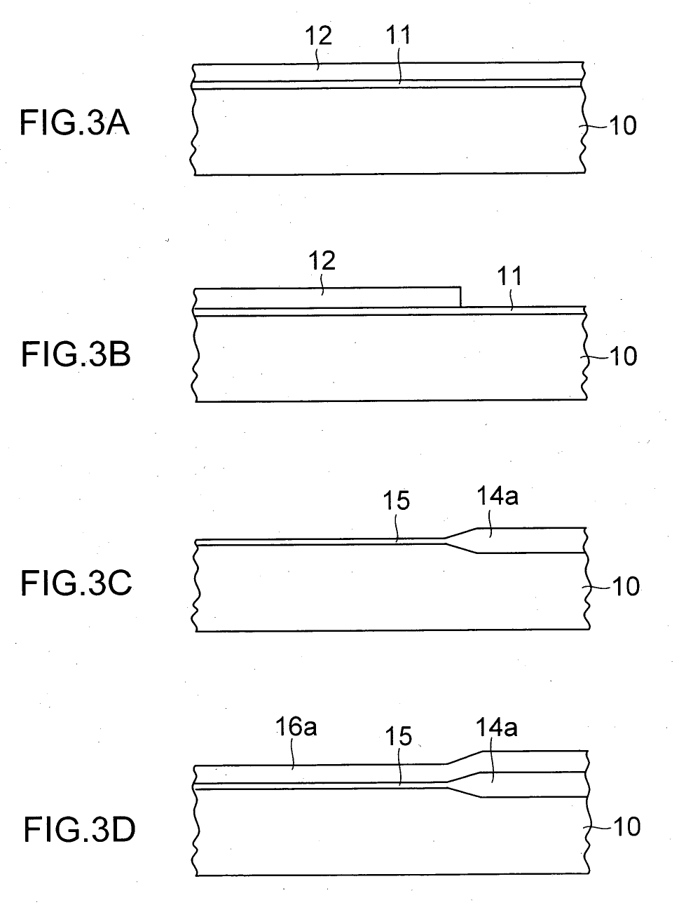

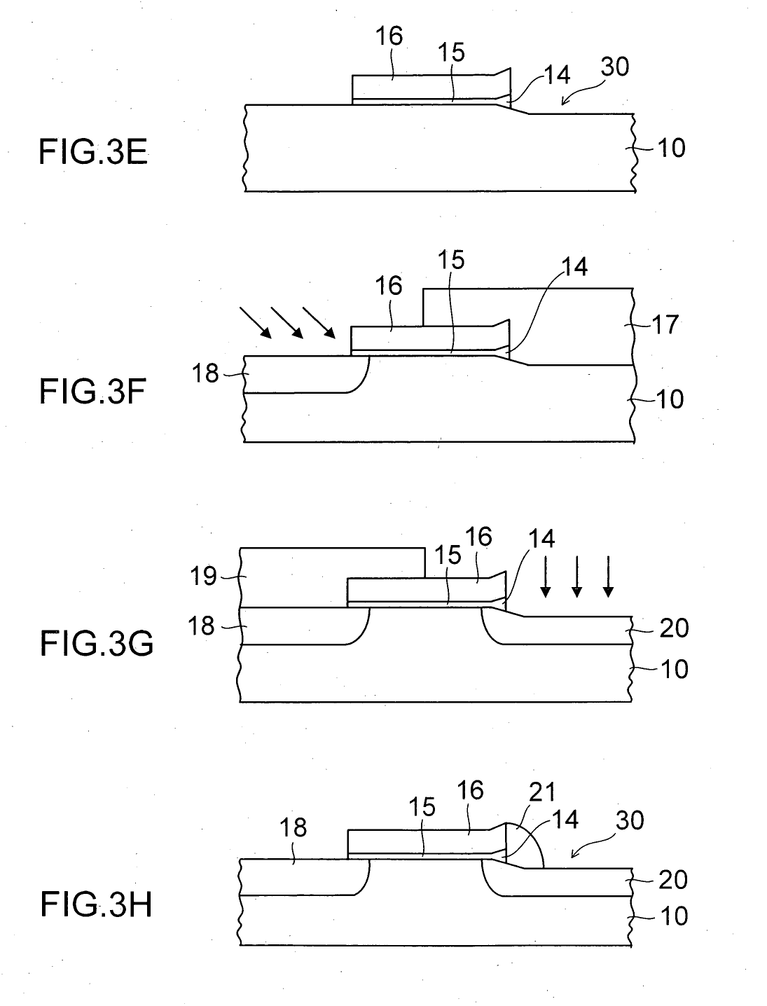

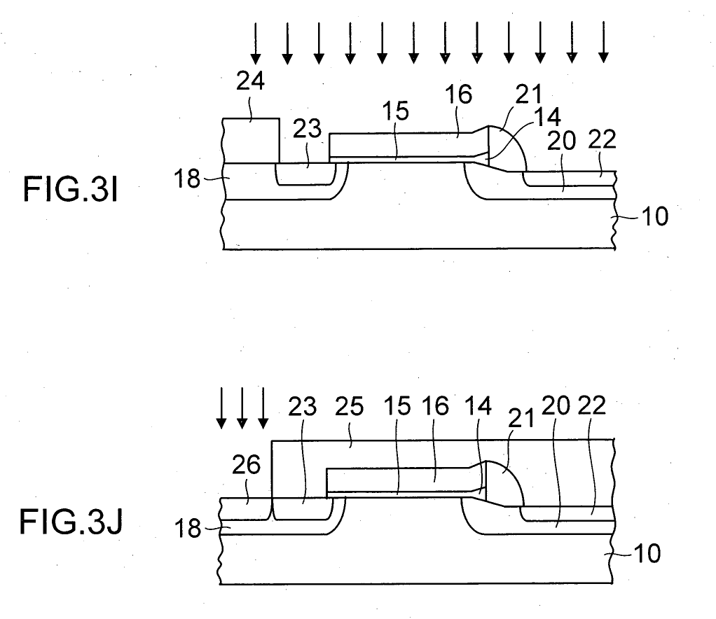

Next, a method of manufacturing the LD-MOS 100 having above described structure will be described. FIGS. 3A to 3J are cross-sectional views showing steps of a process for manufacturing the LD-MOS 100 according to the embodiment of the present invention.

First, a silicon wafer formed with the n-type semiconductor layer 10 is washed with an acid solution, rinsed with ultrapure water, and dried in a centrifugal dryer. Next, the washed wafer is conveyed to a furnace set at an ambient temperature of 900° C., for example, whereupon oxygen is reacted with silicon to form a pad oxide film (SiO₂) 11 on the silicon substrate. A silicon nitride film (Si₃N₄) 12 is then deposited on the pad oxide film (SiO₂) 11 by a thermal reaction between silane (SiH₄) and ammonia (NH₃) (FIG. 3A) . Note that the n-type semiconductor layer 10 may be an n-well region formed by implementing ion implantation on the surface of a p-type semiconductor substrate.

Next, a resist mask (not shown) having an opening on the drain side is formed on the silicon nitride film 12. The silicon nitride film 12 is partially removed by dry etching to expose a part of the pad oxide film 11. The exposed part of the pad oxide film 11 is a part in which a LOCOS film 14a is to be formed in a subsequent step (FIG. 3B).

The resist mask is then washed away. The LOCOS film 14a composed of SiO₂ is grown on the drain side by thermal oxidation method using the silicon nitride film 12 as an oxidation-resistant mask. The silicon nitride film 12 is then removed using hot phosphoric acid (H₃PO₄), whereupon the remaining pad oxide film 11 underneath the silicon nitride film 12 is removed by hydrofluoric acid (HF). Next, A gate oxide film 15 is formed on the n-type semiconductor layer 10 exposed by removing the pad oxide film 11 by a thermal oxidation method. The end portion on the drain side of the gate oxide film 15 is connected to the LOCOS film 14a having a greater film thickness than the gate oxide film 15 (FIG. 3C).

Next, a polysilicon film 16a serving as a conductive film is deposited so as to cover the gate oxide film 15 and the LOCOS film 14a by LP-CVD method using silane (SiH₄) as a reactive gas (FIG. 3D). An appropriate amount of phosphorus (P) maybe doped to the polysilicon film 16a to lower the electric resistance of the polysilicon film 16a.

Next, a resist mask (not shown) is formed on the polysilicon film 16a. The polysilicon film 16a is partially removed by dry etching to form the gate electrode 16. In the dry etching process, the gate patterning is implemented such that the end portion on the drain side of the gate electrode 16 is positioned above an inclined portion at the end portion of the LOCOS film 14a. Next, using the same mask that was used to pattern the gate electrode, the LOCOS film 14a is partially removed by etching such that an end portion of LOCOS film 14a is in alignment with the end portion of the gate electrode 16 to form the thick portion 14 of the gate oxide film 15. In other words, the entire LOCOS film 14a except for the part that contacts the gate electrode 16 is removed. By removing the LOCOS film 14a, a recessed portion 30 having a lower surface than the other portions is formed on the surface of drain said of the n-type semiconductor layer 10 (FIG. 3E).

Next, a resist mask 17 that has an opening on the source side and covers the drain region is formed on the wafer. At this time, the end portion on the source side of the gate electrode 16 may be exposed. Next, using the resist mask 17 and the gate electrode 16 as a mask, boron ions (11B+) serving as a p-type dopant are implanted into the surface of the n-type semiconductor layer 10, whereby the p-body region 18 composed of a p-type semiconductor is formed in a self-aligned manner relative to the gate electrode 16. At this time, an ion implantation energy is set at 40 KeV, a dosage is set at 5.0×10¹³ to 1.0×10¹⁴cm⁻², and a tilt angle is set at 45° , for example. The tilt angle is an angle of an ion beam to a normal line of the wafer surface (FIG. 3F).

Next, a resist mask 19 that has an opening on the drain side and covers the source region is formed on the wafer. At this time, the end portion on the drain side of the gate electrode 16 may be exposed. Next, using the resist mask 19 and the gate electrode 16 as a mask, phosphorus ions (31P+) serving as an n-type dopant are implanted into the surface of the n-type semiconductor layer 10, whereby the electric field relaxation layer 20 composed by a comparatively lightly-doped n-type semiconductor is formed in a self-aligned manner relative to the gate electrode 16. At this time, the ion implantation energy is set at 80 KeV, the dosage is set at 5.0×10¹² to 1.0 ×10¹³cm⁻² , and the tilt angle is set at 0°.

Next, a conformal SiO₂ film, or in other words an SiO₂ film having isotropic step coverage, is deposited on the wafer, whereupon anisotropic etching mainly composed of the vertical component is performed by RIE (reactive ion etching) to form the side wall spacer 21 so as to cover a side surface on the drain side of the gate electrode 16. At this time, the side wall spacer 21 is formed such that a bottom surface of the side wall spacer 21 contacts a surface of the recessed portion 30 formed on the drain side surface of the n-type semiconductor layer 10. Here, a width of the side wall spacer 21 is controlled in accordance with its height . In the LD-MOS 100 according to the embodiment , the recessed portion 30 is formed on the drain side surface of the n-type semiconductor layer 10, and therefore the height of the side wall spacer 21 can be made higher than general LD-MOS. As a result , a sufficient width is secured in the side wall spacer (FIG. 3H).

Next, a resist mask 24 covering the body contact region 26 is formed on the wafer, whereupon the drain region 22 and source region 23 composed of comparatively highly-doped n-type semiconductors are formed by implanting arsenic ions (75As+) serving as an n-type dopant into the p-body region 18 and the electric field relaxation layer 20, respectively, via the resist mask 24. The drain region 22 is formed in a self-aligned manner relative to the gate electrode 16 and the side wall spacer.

At this time, the ion implantation energy is set at 40 KeV, for example, the dosage is set at 5.0×10¹⁵, and the tilt angle is set at 0°. Since the side wall spacer 21 formed at the end portion on the drain side of the gate electrode 16 serves as a mask during the ion implantation, the drain region 22 is not formed below the gate electrode 16 and the side wall spacer 21. As described above, the side wall spacer has a sufficient width, and therefore the electric field relaxation layer 20, which has a comparatively large width in a gate length direction, is interposed between the gate electrode 16 and the drain region 22. As a result, an increase in the withstand voltage of the device can be achieved (FIG. 3I).

Next, a resist mask 25 having an opening in a part that corresponds to the body contact region 26 is formed on the wafer, whereupon the body contact region 26 composed of a comparatively highly-doped p-type semiconductor is formed by implanting boron ions (11B+) serving as a p-type dopant into the p-body region 18 via the resist mask 25 (FIG. 3J).

An inter-layer insulating film is then formed on the wafer, whereupon contact holes for leading out gate, source and drain electrodes are formed in the inter-layer insulating film. Next, a wire AL is formed on the inter-layer insulating film by a vapor deposition method or a sputtering method, whereupon AL wire patterning is implemented. Sintering is then performed in a forming gas of hydrogen (H₂) and nitrogen (N₂), whereby the LD-MOS 100 is completed.

According to the method for manufacturing a semiconductor device of the present invention, sufficient height can be secured in the side wall spacer 21. More specifically, as shown in FIG. 2, a height d5 of the side wall spacer 21 from the silicon substrate surface corresponds to a dimension obtained by adding together a thickness d3 of the thick portion 14 formed at the end portion of the gate electrode, a thickness d4 of the gate electrode 16, and a depth d2 of the recessed portion 30 formed on the silicon substrate by removing the LOCOS film 14a. Therefore the height of the side wall spacer 21 can be made higher in comparison with a case in which a side wall spacer is simply formed on a side surface of a gate electrode after forming a gate oxide film and the gate electrode on a flat surface. As a result, a sufficient width in the gate length direction can also be secured in the side wall spacer 21.

The side wall spacer 21 has a substantially identical function to the LOCOS film 2 of the conventionally structured LD-MOS shown in FIG. 1, i.e. to contribute to an improvement in the gate-drain withstand voltage. Securing a sufficient width in the side wall spacer 21 is equivalent to securing the width of the distance d1 in FIG. 1, and by securing width, a desired gate-drain withstand voltage can be obtained. According to the manufacturing method of a semiconductor device of the present invention, the width of the side wall spacer is controlled in accordance with its height. Therefore, the width of the side wall spacer is not affected by alignment errors of the masks used in the process for forming the LOCOS film, the process for patterning the gate electrode and so on. Hence, measures such as increasing the element size in consideration of the mask shifting are not required.

Note that in the embodiment described above, a case in which the present invention is applied to an n-channel MOSFET was described, but the present invention may be applied to a p-channel MOSFET.

Further, in the embodiment described above, the electric field relaxation layer 20 is formed after forming the gate electrode 16 and before forming the side wall spacer 21, but the electric field relaxation layer 20 may be formed by implementing ion implantation on the silicon substrate after patterning the nitride film 12 and before forming the LOCOS film 14a. In this case, a device having an even higher withstand voltage can be manufactured.

Furthermore, in the embodiment described above, the LOCOS film 14a and side wall spacer 21 are formed only on the drain side, but may be formed on the source side or on both the drain side and the source side.

The present invention was described above with reference to a preferred embodiment thereof. It is to be understood that a person skilled in the art could envisage various amendments and modifications thereto. It is to be assumed that all examples of such amendments and modifications are included within the scope of the attached claims.

This application is based on Japanese Patent Application 2009-06987, which is herein incorporated by reference.

What is claimed is:

1. A method for manufacturing a semiconductor device having a MOS structure, comprising the steps of:
forming a LOCOS film on at least one of a drain side and a source side of a semiconductor substrate surface;
forming a gate oxide film connected to said LOCOS film on said semiconductor substrate surface;
forming a conductive film to cover said gate oxide film and said LOCOS film;
forming a gate electrode by etching said conductive film such that an end portion of said conductive film is positioned above said LOCOS film;
etching said LOCOS film such that an end portion of said LOCOS film is in alignment with an end portion of said gate electrode, thereby forming a recessed portion in a part of said semiconductor substrate surface from which said LOCOS film has been removed;
forming a side wall spacer to cover a side surface of the gate electrode such that a bottom surface of the side wall spacer contacts a surface of the recessed portion; and
forming a drain region and a source region by doping a impurity to said semiconductor substrate surface on either side of said gate electrode and said side wall spacer.

2. The method according to claim 1, wherein said side wall spacer is formed to have a height that extends from the surface of said recessed portion to a top of the end portion of said gate electrode positioned above said LOCOS film.

3. The method according to claim 2, wherein said side wall spacer is formed such that a width thereof in a gate length direction corresponds to the height thereof.

4. The method according to claim 3, further comprising a step of forming an electric field relaxation layer having a lower impurity concentration than an impurity concentration of said drain region by doping a impurity to a drain formation region on said semiconductor substrate surface before forming said side wall spacer.

5. The method according to claim 4, wherein said electric field relaxation layer is formed by performing ion implantation using said gate electrode as a mask, and said drain region and said source region are formed by performing ion implantation using said gate electrode and said side wall spacer as a mask.

6. A semiconductor device having a MOS structure, comprising:
a gate oxide film including a thick portion that is formed on at least one of a drain side and a source side of a semiconductor substrate surface and has a greater film thickness than other part of said gate oxide film;
a gate electrode provided on said gate oxide film;
a side wall spacer that covers a side surface of said gate electrode on a side formed with said thick portion; and
a drain region and a source region provided on either side of said gate electrode and said side wall spacer on said semiconductor substrate surface,
wherein said semiconductor substrate includes a recessed portion having a lower surface than another part, and
a bottom surface of said side wall spacer contacts a surface of said recessed portion.

7. The semiconductor device according to claim 6, wherein an electric field relaxation layer having a lower impurity concentration than an impurity concentration of said drain region is provided between said gate electrode and said drain region.

8. The semiconductor device according to claim 7, wherein said source region is composed of an n-type semiconductor layer formed in a p-body region that is composed of a p-type semiconductor and formed on said semiconductor substrate surface,
said drain region is composed of an n-type semiconductor layer provided in said electric field relaxation layer, and
said side wall spacer is provided only on a drain side of said gate electrode.

9. The method according to claim 1, wherein said LOCOS film has a greater film thickness than said gate oxide film.

10. The semiconductor device according to claim 6, wherein said side wall spacer interposes between said gate electrode and said drain region or said source region.

11. The semiconductor device according to claim 6, wherein said thick portion is formed by patterning a LOCOS film.
